(19) United States
(12) Patent Application Publication
(10) Pub. No.: US 2013/0270514 A1
(43) Pub. Date: Oct. 17, 2013

(54) LOW RESISTANCE BIDIRECTIONAL JUNCTIONS IN WIDE BANDGAP SEMICONDUCTOR MATERIALS

(71) Applicant: Adam William Saxler, Cary, NC (US)

(72) Inventor: Adam William Saxler, Cary, NC (US)

(21) Appl. No.: 13/447,915

(22) Filed: Apr. 16, 2012

(51) Int. Cl. H01L 33/06; H01L 29/38

(52) U.S. Cl. 257/13; 257/12; 257/E33.008; 257/E29.105

(57) ABSTRACT

A light emitting diode device includes a first diode structure, a second diode structure on the first diode structure, and a conductive junction between the first diode structure and the second diode structure. The conductive junction includes a transparent conductive layer between the first diode structure and the second diode structure. Low resistance heterojunction tunnel junction structures including delta-doped layers are also disclosed.

### BACKGROUND

1. Field of the Invention

The present invention relates to semiconductor devices formed in wide band gap materials, and in particular to fabricating low resistance junctions in wide band gap materials.

2. Description of the Related Art

Semiconductor materials can be doped with impurities to be p-type materials in which positive charge carriers (e.g. holes) predominate or n-type materials in which negative charge carriers (e.g. electrons) predominate. Metallurgical junctions between differently doped regions of a single semiconductor material are called homojunctions. These junctions are formed, for example, when a single material abruptly transitions from one type of doping to another.

A p-n junction consists of a p-type region and an n-type region in metallurgical contact with each other. When the p-type region and the n-type region comprise the same semiconductor material, the junction is referred to has a homojunction. Junctions between different types of semiconductor materials are referred to as heterojunctions.

When a p-n junction is formed, electrons and holes diffuse from areas of high concentration towards areas of low concentration. Thus, electrons diffuse away from the n-type region into the p-type region, leaving behind fixed (immobile) positively charged ionized donor atoms in the n-type region. In the p-type region, the electrons recombine with abundant holes. Similarly, holes diffuse away from the p-type region, leaving behind negatively charged ionized acceptor atoms. In the n-type region, the holes recombine with abundant mobile electrons.

The positive and negatively charged ions around the junction form a dipole that has a built-in voltage at the junction that opposes the diffusion of carriers. At equilibrium, the built-in voltage of the dipole is just large enough to prevent any further diffusion of =Tiers.

As a result of the diffusion of carriers and the resulting dipole, a narrow region on both sides of the junction becomes almost totally depleted of mobile charged carriers (i.e., any mobile carriers are swept across the junction by the built-in voltage generated by the dipole). This region is called the depletion layer. The thickness of the depletion layer in the junction is inversely proportional to the concentration of dopants in the region.

A p-n homojunction typically will act as a rectifier that permits current to flow in one direction but blocks current in the reverse direction. That is, when a positive voltage is applied to the p-type region, the built-in voltage will be reduced, decreasing the width of the depletion region and permitting diffusion of carriers across the junction, thereby allowing current flow. Conversely, when a positive voltage is applied to the n-type region, the depletion region expands, blocking current flow across the junction.

If the regions on opposite sides of the junction are doped highly enough, a tunnel diode may be formed. In a tunnel diode, the width of the depletion region is so small that carriers can “tunnel” through the potential barrier presented by the built-in voltage, permitting current flow in the reverse direction. The width of the depletion region of a tunnel diode is therefore called a tunnel distance, or tunnel width.

A conventional tunnel diode includes a p-n homojunction in which both the p and n sides are degenerately doped. “Degenerate” or “degenerative” doping refers to very high doping concentrations in a semiconductor material, e.g., more than about 5E18 dopants per cubic centimeter. Degenerate doping is typically denoted with a ‘++’ symbol, such as n++, or p++. The depletion region, or tunnel width, is inversely proportional to the square root of the charge carrier density (the number of charge carriers per cubic centimeter) of the materials used to form the junction, and is directly proportional to the size of the material's band gap.

To cause tunneling to occur, a bias voltage is applied across a tunnel diode. The tunneling resistance of a tunnel junction is defined as the bias divided by current. Under certain conditions, the tunneling resistance can be low enough that the tunnel diode current-voltage relationship is essentially ohmic (linear). Three primary factors determine the tunneling resistance: the density of free electrons on one side of the junction, the density of holes on the other side, and the tunneling probability. The higher the value of these parameters, the lower the tunneling resistance. While it is generally a complex function of the details of the tunnel junction, the tunneling probability decreases roughly exponentially with tunneling distance. Thus, tunneling resistance is reduced when the tunnel width is as small as possible.

Degenerative doping of the materials that form the tunnel junction reduces the tunnel width across which the charge carriers need to tunnel. Unfortunately, there is an upper limit to how heavily a semiconductor material can be doped. All dopants eventually reach a saturation solubility limit at which the material is no longer capable of absorbing further dopants without changing its composition. Once this saturation limit is reached, doping loses its ability to reduce the tunnel width. Furthermore, as the charge density increases the dopant ionization probability decreases according to basic semiconductor statistics, again limiting the ability of doping to reduce the tunnel width.

Homojunction tunnel junctions may be fabricated in periodic table group III-nitride semiconductor materials. Such materials include, but are not limited to, indium nitride, gallium nitride and aluminum nitride, and combinations thereof. One difficulty with these nitride materials is that their band gap is significantly larger than the band gap of other III-V compound semiconductor materials (i.e., compound semiconductor materials including at least one element from column IIIA of the periodic table and at least one element from column VA of the periodic table). For example, gallium nitride has a band gap of roughly 3.4 electron volts (eV), while gallium arsenide (also a III-V semiconductor material) has a band gap of approximately 1.4 electron volts. This band gap difference is significant, because a larger band gap results in a larger, or wider, tunnel width. A tunnel junction with low tunneling resistance is very difficult to form in wide band gap materials such as gallium nitride or silicon carbide.

### SUMMARY

A light emitting diode device according to some embodiments includes a first diode structure, a second diode structure on the first diode structure, and a conductive junction between the first diode structure and the second diode structure. The conductive junction may include a transparent conductive layer between the first diode structure and the second diode structure.

The transparent conductive layer may include a transparent conductive oxide.

The transparent conductive oxide may include indium tin oxide and/or zinc oxide.

The first diode structure may include a p-type semiconductor layer, the second diode structure may include an n-type semiconductor layer, and the transparent conductive layer may be interposed between and contacts the p-type semiconductor layer and the n-type semiconductor layer.

In some embodiments, the transparent conductive layer may form an ohmic contact to the p-type semiconductor layer and the n-type semiconductor layer.

The transparent conductive layer may include a layered structure including a first transparent conductive layer and a second transparent conductive layer on the first transparent conductive layer. The second transparent conductive layer may include a different material than the first transparent conductive layer. The first transparent conductive layer may include a metal layer and the second transparent conductive layer may include a transparent conductive oxide. In some embodiments, the first transparent conductive layer may include a first transparent conductive oxide and the second transparent conductive layer may include a second transparent conductive oxide.

The first transparent conductive layer may form an ohmic contact to the p-type semiconductor layer and the second transparent conductive layer may form an ohmic contact to the n-type semiconductor layer.

The transparent conductive layer may include a plurality of apertures, the p-type semiconductor layer contacts the n-type semiconductor layer through the apertures.

The device may further include a third diode structure on the second diode structure and a second transparent conductive layer between the second diode structure and the third diode structure. The plurality of apertures may include a first plurality of apertures, the second transparent conductive layer may include a second plurality of apertures, and the second diode structure contacts the third diode structure through the second plurality of apertures. The first plurality of apertures may be horizontally offset from the second plurality of apertures.

The material of the first diode structure and the second diode structure may have a first index of refraction, and a material of the first transparent conductive layer and the second transparent conductive layer may have a second index of refraction that may be different than the first index of refraction.

The light emitting diode device may further include a fourth diode structure on the third diode structure and a third transparent conductive layer between the third diode structure and the fourth diode structure. A distance between the first transparent conductive layer and the second transparent conductive layer may be different than a distance between the second transparent conductive layer and the third transparent conductive layer.

The first plurality of apertures and the second plurality of apertures may be configured to cause the first transparent conductive layer and the second transparent conductive layer to scatter light passing within the light emitting diode device.

Thicknesses of the first second and third diode structures and the first and second transparent conductive layers may be selected to cause an effective index of refraction of the light emitting diode device to be less than index of refraction of the material of the first second and third lightning diode structures.

Thicknesses of the first second and third diode structures and the first and second transparent conductive layers may be selected to reduce the reflectivity of the structure at a predetermined wavelength of light.

The light emitting diode device may further include a trench through the second light emitting diode structure.

The trench extends to the first light emitting diode structure.

The light emitting diode device may further include a void between the first light emitting diode structure and the second light emitting diode structure adjacent the transparent conductive layer.

A light emitting diode device according to further embodiments includes a diode structure including an n-type layer, an active layer on the n-type layer, and a p-type layer on the active layer, and a conductive junction on p-type layer opposite the active layer. The conductive junction may include a transparent conductive layer.

A low resistance tunnel junction structure according to further embodiments includes first and second semiconductor layers, wherein the first layer may be non-degenerately doped with n-type dopants, and the second layer may be non-degenerately doped with p-type dopants, and a third semiconductor layer between the first and second semiconductor layers and forming first and second heterojunctions with the first and second layers respectively. The third semiconductor layer has a different bandgap than the first and second layers. The first, second and third layers have an associated natural polarization dipole that causes a tunneling distance between the first and second semiconductor layers to be smaller than it would be in the absence of the third layer. structure further may include a delta-doped region in the first semiconductor layer adjacent the first heterojunction. The delta-doped region may be doped with n-type dopants at a doping concentration greater than 5E18 cm-3.

The structure may further include a second delta-doped region in the second semiconductor layer adjacent the second heterojunction. The second delta-doped region may be doped with p-type dopants at a doping concentration greater than 5E18 cm⁻³.

The third layer may be about 0.5 to 10 nanometers thick.

The structure may include a periodic table group III-nitride material system.

The third layer may include indium gallium nitride (InxGayN), where x+y=1 and x>0 or aluminum gallium nitride (AlxGayN), where x+y=1 and x>0.

The third layer may forms abrupt or graded transitions with the first and second layers.

The third layer may include an impurity that forms both deep level and shallow level bandgap states within the third layer that further reduces the tunneling distance between the first and second semiconductor layers.

The third layer may include a first sub-layer doped with a double p-type dopant that forms both deep level and shallow level acceptor states and a second sub-layer doped with a double n-type dopant that forms both deep level and shallow level donor states.

The first and second sub-layers may be about 0.3 to 5 nanometers thick.

### BRIEF DESCRIPTION OF THE DRAWINGS

These and other features and advantages of the invention will be apparent to those skilled in the art from the following detailed description, taken together with the accompanying drawings, in which:

FIGS. 1 and 2 are plan views of semiconductor structures including non-rectifying conductive interfaces according to some embodiments.

FIGS. 3A and 3B are cross sectional views of the semiconductor structure of FIG. 1 taken along lines A-A and B-B, respectively.

FIGS. 4A, 4B and 4C are cross sectional views of semiconductor structures including non-rectifying conductive interfaces according to further embodiments.

FIGS. 5, 6, 7 and 8 are cross sectional views of semiconductor structures including non-rectifying conductive interfaces according to further embodiments.

FIG. 9A is a cross sectional illustration of a semiconductor structure including a tunnel junction.

FIG. 9B is a band diagram of the semiconductor structure shown in FIG. 9A.

FIG. 10A is a cross sectional illustration of a semiconductor structure including a tunnel junction according to some embodiments.

FIG. 10B is a detailed cross sectional view of the tunnel junction of FIG. 10A.

FIG. 10C is a band diagram of the semiconductor structure shown in FIG. 10A.

FIG. 11A is a cross sectional illustration of a semiconductor structure including a tunnel junction according to some embodiments.

FIG. 11B is a detailed cross sectional view of the tunnel junction of FIG. 11A.

FIG. 11C is a band diagram of the semiconductor structure shown in FIG. 11A.

FIGS. 12, 13, 14 and 15 are cross sectional views of semiconductor structures including tunnel junctions according to further embodiments.

FIG. 16 is a band diagram of the semiconductor structure shown in FIG. 15.

FIG. 17 is a cross sectional view of a semiconductor structure including a tunnel junction according to further embodiments.

### DETAILED DESCRIPTION OF EMBODIMENTS

Some embodiments of the invention provide non-rectifying conductive interfaces between p-type and n-type semiconductor layers. A non-rectifying conductive interface permits current to flow bidirectionally between the p-type and n-type layers, e.g., when a forward or reverse voltage is applied to the semiconductor layers.

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “between”, “below,” “above,” “upper,” “lower,” “horizontal,” “lateral,” “vertical,” “beneath,” “over,” “on,” etc., may be used herein to describe a relationship of one element, layer or region to another element, layer or region as illustrated in the figures. It will be understood that these terms are intended to encompass different orientations of the device in addition to the orientation depicted in the figures.

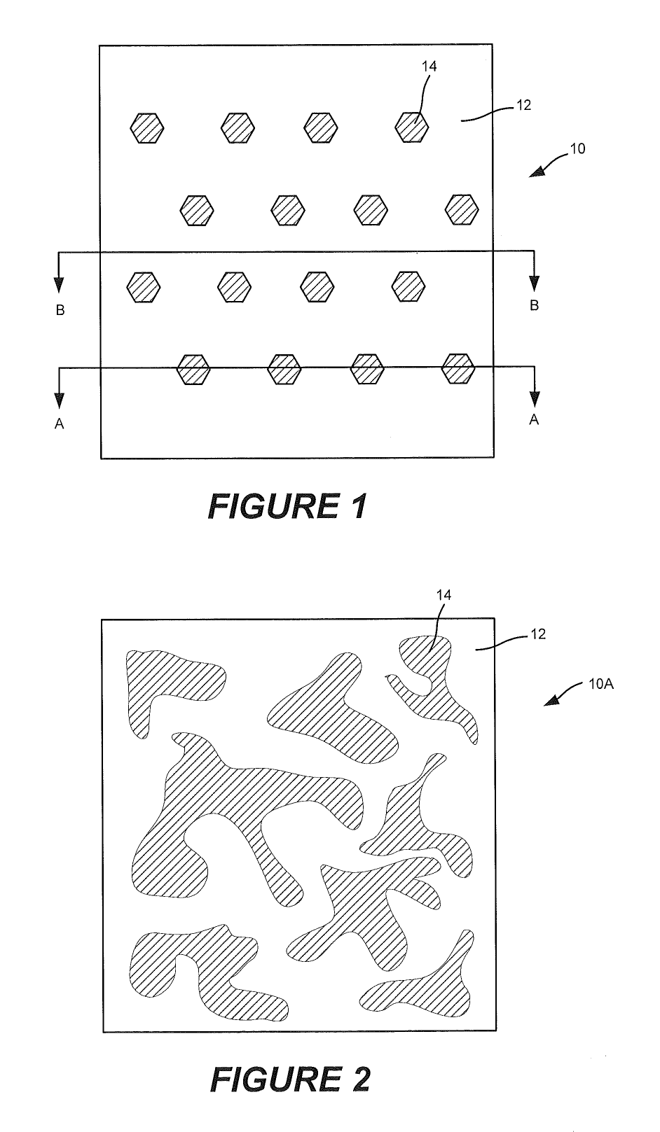

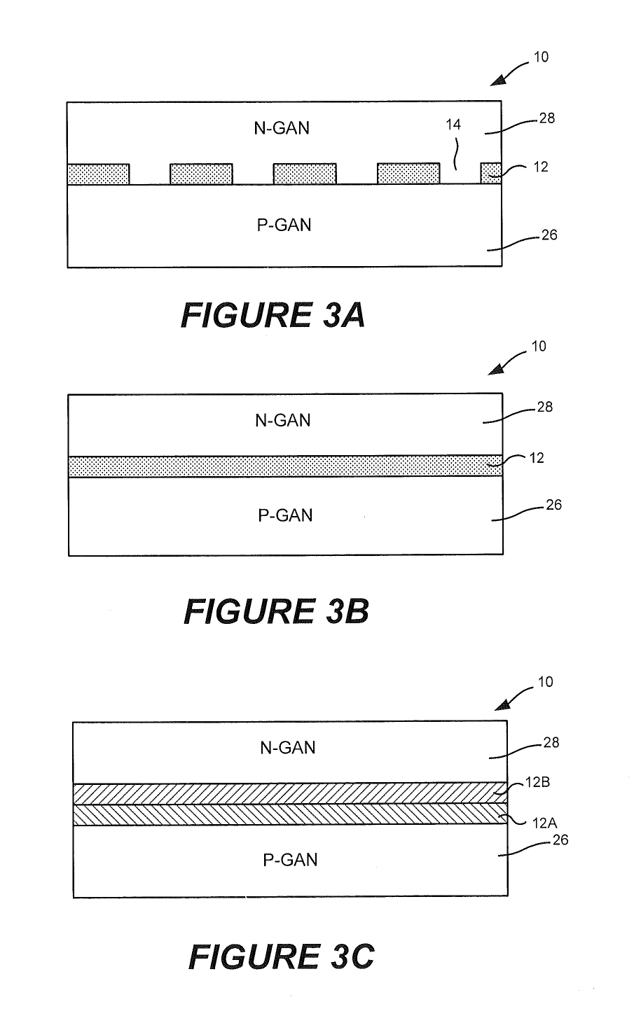

FIGS. 1 and 2 are plan views of semiconductor structures including non-rectifying conductive interfaces according to some embodiments. FIGS. 3A and 3B are cross sectional views of the semiconductor structure of FIG. 1 taken along lines A-A and B-B, respectively.

Referring to FIGS. 1, 2 and 3A-3B, a semiconductor structure 10 according to some embodiments includes an a p-type semiconductor layer 26 and an n-type semiconductor layer 28. The semiconductor layers 26, 28 may, for example, include Group III-nitride materials, such as GaN, AlGaN, InGaN, etc. A conductive layer 12 is provided between the p-type semiconductor layer 26 and the n-type semiconductor layer 28 and provides a conductive path between the two layers. In particular, the conductive layer 12 forms a conductive interface with both the p-type layer 26 and the n-type layer 28. Although the p-type layer 26 is shown beneath the n-type layer 28 in FIGS. 2A and 2B, the order of the layers could be reversed.

As discussed in more detail below, in some embodiments, the conductive layer 12 comprises a transparent conductive material, such as a transparent conductive oxide and/or a transparent conductive metal, that can form a conductive contact to both the n-type and p-type semiconductor layers 26, 28.

The transparent conductive layer 12 may be a discontinuous layer. That is, the transparent conductive layer 12 may not fully cover the underlying p-type layer 26. In particular, the transparent conductive layer 12 may include gaps 14 therein through which the n-type layer 28 contacts the p-type layer 26. The gaps 14 are provided so that the n-type layer 28 can be epitaxially grown from the p-type layer 26, for example, using an epitaxial growth technique such as metal-organic chemical vapor deposition (MOCVD), molecular beam epitaxy (MBE) or similar processes.

In some embodiments, the transparent conductive layer 14 may be formed to continuously cover the underlying layer, and the gaps 14 may be formed lithographically. For example, a continuous transparent conductive layer 12 may be grown or formed on the p-type layer 26 and then masked and etched to form the gaps 14 therein. In other embodiments, the gaps 14 may be formed naturally by depositing the transparent conductive layer 12 to be a thin discontinuous layer that does not provide complete coverage of the underlying p-type layer 26, as illustrated in FIG. 2.

Referring to FIG. 3C, the transparent conductive layer 12 may include a first transparent conductive layer 12A and a second transparent conductive layer 12B. The first transparent conductive layer 12A may form an ohmic contact with the p-type layer 26, while the second transparent conductive layer 12B may form an ohmic contact with the n-type layer 28 and with the first transparent conductive layer 12A to provide a non-rectifying conductive interface from the p-type layer 26 to the n-type layer 28.

In some embodiments, one of the first and second transparent conductive layers 12A, 12B may include a transparent conductive oxide, such as indium tin oxide, zinc oxide, etc., while the other transparent conductive layer may include a thin metal layer. In some embodiments, at least one of the transparent conductive layers may include titanium nitride (TiN), which can be grown in-situ in the epitaxial growth reactor in which the nitride semiconductor layers of the structure are formed. TiN can be grown thin to maintain transparency and to avoid forming a continuous layer over the underlying semiconductor layer. TiN can also be grown ex-situ, and can in some embodiments be grown thicker and then patterned to form openings 14 therein.

To make ohmic contact between n-type and p-type layer with minimal resistance, two or more transparent conductors or thin metals with different work functions may be chosen to make ohmic contacts to both the N and P sides.

The transparent conductive layers may be doped very heavily so that tunneling conduction may occur. A fluoride doped transparent conductive oxide, such as ZnO:F may have better mobility than a metal doped oxide. In some embodiments, it may also be desirable to grade the material composition between the two transparent conductive layers to reduce any potential barrier between them. Germanium may be doped into the transparent conductive layers to reduce or avoid cracking of the nitride semiconductor layer near the transparent conductive layers.

In some embodiments, the n-type layer 28 is formed through an epitaxial lateral overgrowth (“ELO”) technique in which the layer is grown epitaxially from the underlying p-type layer through the openings 14 and then laterally across the transparent conductive layer 12. As used herein, the term “epitaxial lateral overgrowth” refers to a type of growth technique and resulting structure that is described in (for example) U.S. Pat. No. 6,051,849 to Davis et al., which issued on Apr. 18, 2000, U.S. Pat. No. 6,265,289 issued Jul. 24, 2001, U.S. Pat. No. 6,177,688 issued Jan. 23, 2001 and in co-pending application Ser. No. 08/031,843 filed Feb. 27, 1998 for “Methods of Fabricating Gallium Nitride Semiconductor Layers by Lateral Overgrowth Through Offset Masks, and Gallium Nitride Semiconductor Structures Fabricated Thereby.” A so-called “single step” technique for performing epitaxial lateral overgrowth is described in co-pending application Ser. No. 09/679,799 filed Oct. 5, 2000 for “Single-Step Pendeo and Lateral Epitaxial Overgrowth of Group III-Nitride Epitaxial Layers with Group III-Nitride Buffer Layer and Resulting Structures.” The disclosures of the '849, '289 and '688 patents and the '843, and '799 applications are each incorporated entirely herein by reference.

Although the technique of epitaxial lateral overgrowth is not a necessary aspect of the invention, it does offer certain advantages, some of which will be described with respect to the method aspects of the invention. In the example of the use of the ELO growth process in connection with the present invention, the n-type layer 28 is grown from the exposed surface of p-type layer 26 vertically through the openings 14 in the transparent conductive layer 12 and then horizontally across the transparent conductive layer 12. In that respect, the transparent conductive layer 12 provides a non-rectifying conductive path between layers 26 and 28, and also serves as the patterned mask layer used to obtain ELO growth as described in the above-mentioned patent and applications.

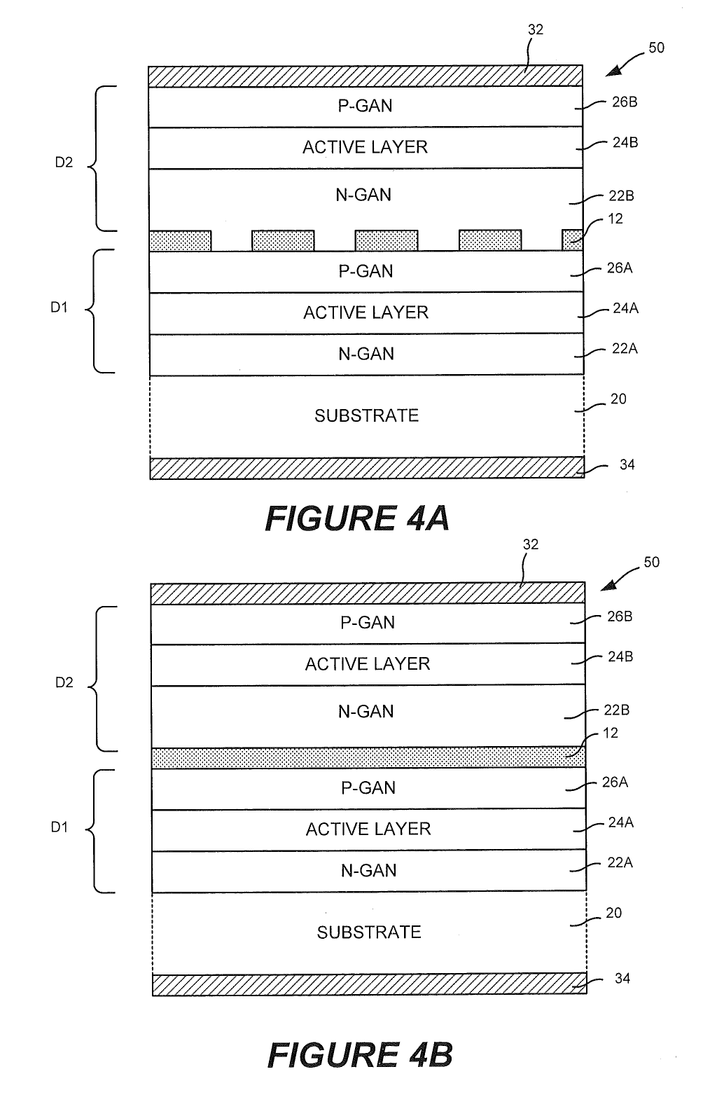

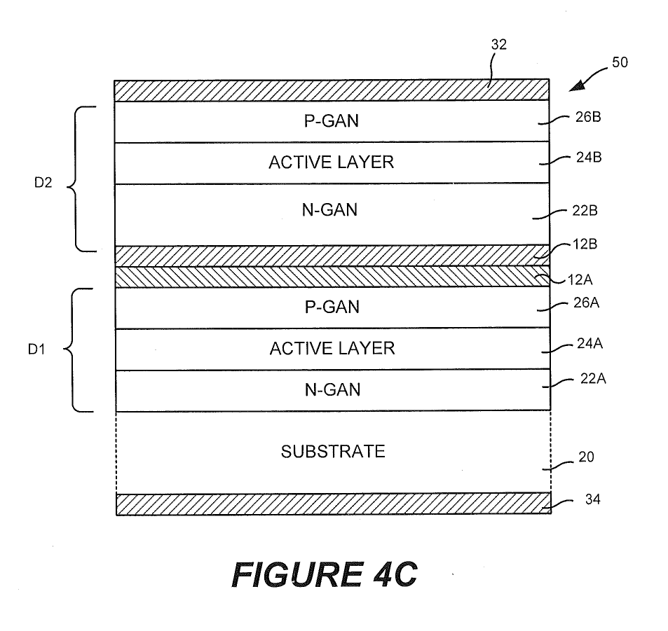

Referring to FIGS. 4A-4C, an optoelectronic structure 50 including low resistance non-rectifying junctions according to some embodiments is illustrated. The structure 50 includes multiple stacked active regions separated by non-rectifying junctions that permit current to flow through the device to energize the active regions simultaneously.

Referring to FIGS. 4A-4C, the structure 50 is a stacked semiconductor structure including an optional substrate 20, on which an n-type layer 22A and an active layer 24A are formed. The active layer 24A is between the n-type layer 22A and a p-type layer 26A. The substrate 20 may include, for example, silicon carbide, sapphire, gallium nitride, or any other suitable substrate material on which group III-nitride materials may be grown.

The active layer 24A may include a single quantum well, a multiple quantum well, a double heterostructure, a single heterostructure, etc., all of which are well known in the art.

An n-type layer 22B is formed on the p-type layer 26A, and a conductive interface 12 is provided between the n-type layer 22B and the p-type layer 26A.

A second active layer 24B may be formed on the n-type semiconductor layer 22B, and a p-type layer 26B is formed on the second active layer 24B. The second active layer 24B may be similar to the first active layer 24A in that it may include a single or multiple quantum well active layer, a double heterostructure, etc. However, the material composition of the first and second active layers 24A, 24B may be different. In some embodiments, the second active region 24B may be configured to emit photons having different wavelengths than are emitted by the first active layer 24A.

Referring to FIG. 4C, the structure 50 may also include a first transparent conductive layer and a second transparent conductive layer 12B between the p-type layer 26A and the n-type layer 22B.

An anode contact 32 may be formed on the p-type layer 26B, and a cathode contact 34 may be formed on the substrate 20 and/or on the n-type layer 22A. It will be appreciated that an additional n-type layer (not shown) could be provided on the p-type layer 26B with a non-rectifying conductive interface between the additional n-type layer and the p-type layer 26B, and the anode contact 32 may be formed on the additional n-type layer.

By providing an additional n-type layer as the top layer of the structure 50, it may be unnecessary to provide a metal ohmic contact on the p-type layer 26B. As is known in the art, it is difficult to form low resistance ohmic contacts to p-type Group III-nitride materials. Moreover, p-type group III-nitride materials generally do not spread current well, resulting in localization of current, which can decrease the quantum efficiency of an optoelectronic device. The additional n-type layer may function as a current spreading layer to provide more even distribution of current in the device.

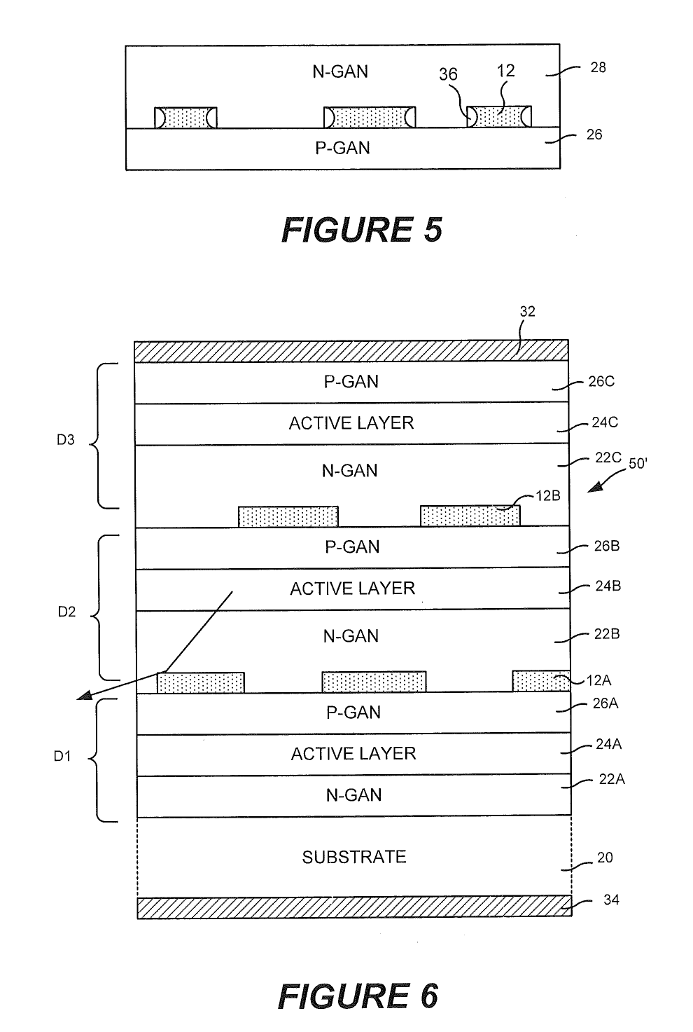

Referring to FIG. 5, the transparent conductive layer 12 may be formed between the p-type layer 26 and the n-type layer 28 so that voids or gaps 36 are formed adjacent the transparent conductive regions. The gaps 36 may provide low refractive index inclusions in the structure that can scatter light generated in the active regions, as discussed in more detail below.

Referring now to FIG. 6, an optoelectronic device 50′ having multiple stacked active regions can be fabricated using transparent conductive interfaces as described herein. As shown therein, a stacked semiconductor structure is formed on an optional substrate 20 and includes first, second and third diode structures D1, D2 and D3 stacked so that they can be energized in series. The first diode structure D1 includes an n-type layer 22A, an active region 24A and a p-type region 26A. The second diode structure D2 includes an n-type layer 22B on the p-type layer 26A of the first diode structure 30A, an active region 24B and a p-type region 26B. The third diode structure D3 includes an n-type layer 22C on the p-type layer 26B of the second diode structure 30B, an active region 24C and a p-type region 26C. An anode contact 32 is formed on the uppermost p-type layer 26C, while a cathode contact 34 is formed on the substrate 20 (or, if the substrate is omitted, on the lowermost n-type layer 22A.)

Conductive interfaces as described above are provided between the p-type layer 26A of the first diode structure D1 and the n-type layer 22B of the second diode structure D2, as well as between the p-type layer 26B of the second diode structure 30B and the n-type layer 22C of the third diode structure D3.

The structure in FIG. 6 allows for the formation of multiple optoelectronic devices in series in a single device structure. In some embodiments, each active layer 24A-24C can comprise a different material composition. The wavelength of light generated by an active region is a function of the band gap and quantum well thickness of that active region, and the band gap of an active region is determined by its composition. Having different compositions allows each of the three active layers 24A-24C to generate different wavelengths, or colors, of light. These wavelengths of light can then combine with one another to a fourth and different wavelength of light. In one embodiment according to the present invention, the light from the active layers 24A-24C can emit different wavelengths of light that combine to produce white light.

Furthermore, the structure in FIG. 6 allows for the possibility of operating optoelectronic devices at current densities where the device efficiency is increased. GaN wide band gap photonic devices have an efficiency peak at forward currents of approximately 2-5 miliamps (mA) for a device having peripheral dimensions of 0.25 mm×0.25 mm. This embodiment would increase the light output at low input power as well. An optoelectronic device including three active regions in series, for instance, could operate at 12 volts and 5 mA and achieve approximately a 30% higher light output due to the higher quantum efficiency at low current densities than a single LED operating at 3 volts and 20 mA.

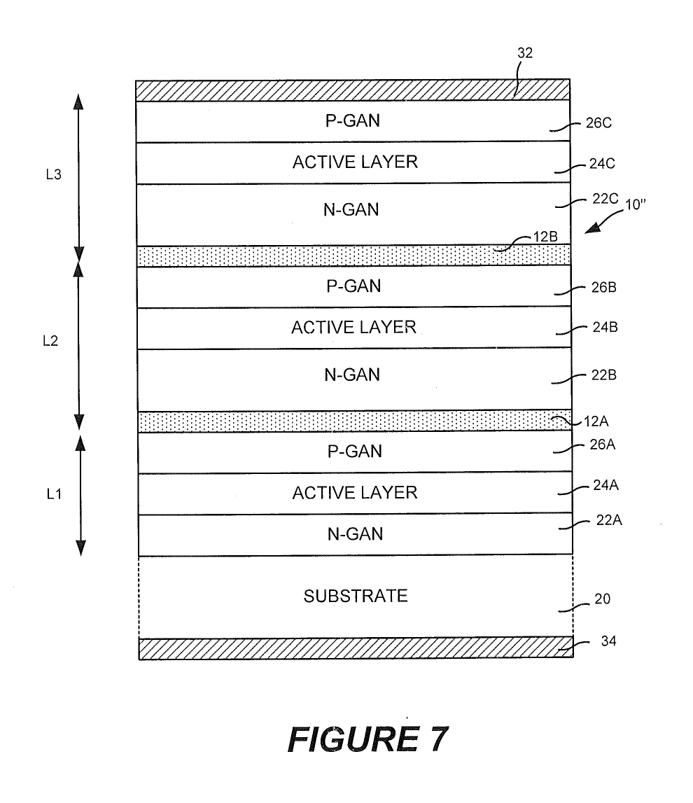

Referring to FIG. 7, the thicknesses L1-L3 of the diode structures D1-D3 may be designed so that the distances between adjacent ones of the transparent conductive layers are spaced a desired distance apart. For example, it may be desirable for the transparent conductive layers to be spaced apart at varying distances to reduce the possibility that the transparent conductive layers could form a resonant cavity within the device structure. As is known in the art, when multiple layers of materials having different refractive indices are stacked in a structure, the resulting structure can reflect certain wavelengths of light. When this is done intentionally, the structure is referred to as a Bragg reflector. Bragg reflectors are particularly useful in devices such as vertical cavity semiconductor laser devices in which an optical cavity is used to amplify light traveling in a particular direction. However, in conventional LED devices, it is generally desirable to extract as much light as possible from the structure in any direction possible.

In some embodiments, the spacing of the transparent conductive layers may be chosen to increase the amount of light extracted from the structure. For example, layered materials having appropriately chosen thicknesses and indices of refraction can have an antireflective effect on light at certain wavelengths.

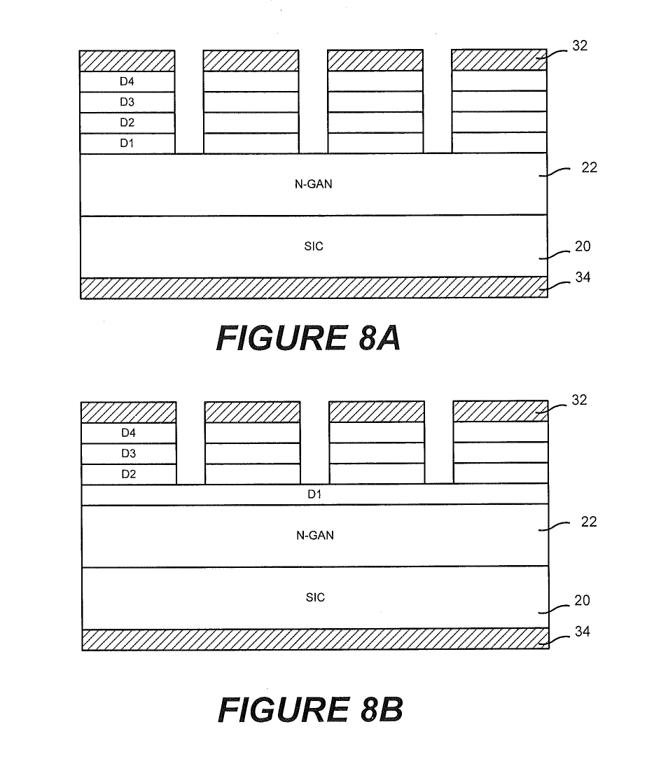

Referring now to FIGS. 8A and 8B, a device according to some embodiments including multiple stacked diode regions D1-D4 may include trenches or holes 46 formed therein that extend through one or more of the diode structures of the device. The trenches or holes 46 may permit light generated in one of the diode structures to escape from the structure more efficiently to reduce the possibility of reabsorption by another one of the diode structures. The trenches or holes 46 may extend through all of the diode structures as shown in FIG. 8A or only through some of the diode structures as shown in FIG. 8B.

Typical tunnel junctions just rely on heavy doping. Approaches in this invention also use band engineering and the piezoelectric effect to reduce the effective resistance of the tunnel junction. Other materials such as ITO may also be introduced at the junction to reduce the voltage drop between the LEDs and increase efficiency. In some embodiments, the material between the LEDs may be patterned between growths of the LEDs to allow nucleation sites for lateral overgrowth.

Conductive junctions as described herein can be used to form low-cost LEDs with higher operating voltages and/or light outputs. Some embodiments may also facilitate the formation of multicolored LEDs capable of generating white light and/or light that produces white light with higher color rendering index when combined with light from appropriately selected phosphors. Other potential applications include solar cells that capture multiple wavelengths. Embodiments of the invention can also be used to make a tunnel junction in a single LED to avoid making a p-type contact. A thick n-type gallium nitride layer could be grown for current spreading.

Some embodiments provide n-type GaN or InAlGaN that is hyper doped with silicon, germanium and/or oxygen that is transparent and conductive and has a low junction barrier to p-type gallium nitride.

A transparent interface according to some embodiments may absorb less than 1% of incident light at 450 nm and may have less than 50 ohms per square sheet resistance.

To avoid cracking in the current spreading III-nitride layers, a low temperature aluminum nitride monolayer may be added to the device structure. Due to the high bandgap of AIN, such a layer should not reabsorb emitted light.

Other embodiments of the invention provide a low resistance tunnel junction structure in wide band gap materials. These junctions may be fabricated from periodic table of the elements groups III-V and II-VI compound semiconductors, whose crystal layers are grown normal to a polar direction of the crystal. In one embodiment, the tunnel junction structures are presumed to have the Wurtzite crystal structure with layers comprising gallium nitride GaN, indium gallium nitride InₓGa_{y}N, and aluminum gallium nitride AlₓGa_{y}N where 0.3<=x<=1.0 and x+y=1.0. In this embodiment, except where noted, the top surface of the crystal has (0001) orientation with Periodic Table group III polarity.

In preferred embodiments, all of the layers are prepared by epitaxial growth methods, although it will be understood that appropriate growth or processing techniques could produce very similar structures. Material composition and doping are uniform over the epitaxial growth surface at any given time; but may vary in the direction of growth. Typically, these structures are grown by molecular beam epitaxy (MBE) or metal organic chemical vapor deposition (MOCVD), but other methods may also be used. An arrow in the accompanying figures indicates the direction of growth.

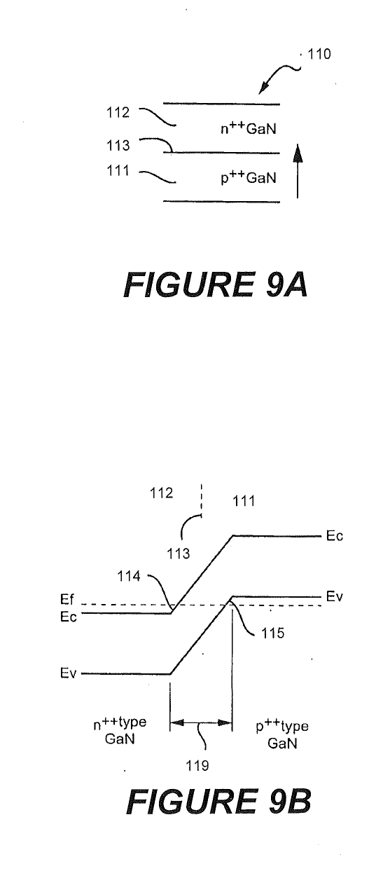

FIG. 9A illustrates a layer structure of a conventional tunnel junction 110, while FIG. 9B is a band diagram of a conventional tunnel junction. A conventional tunnel junction 110 includes a degenerately doped p-type layer 111 on which is grown a degenerately doped n-type semiconductor layer 112. As used herein, the term “degenerate” has its ordinary meaning for n-type GaN, i.e. a semiconductor material that has been extremely heavily doped with desirable impurities to give it an almost metal like ability to conduct current. As an example, degenerately doping an n-type layer of gallium nitride may result in a doping concentration of approximately 5E18 carriers per cubic centimeter (1/cm3). In the case of p-type gallium nitride, it is well known that it is not possible to achieve degenerate doping in the ordinary sense due to the unavailability of acceptor impurities with suitably low activation energy. However neither the term, “degenerate” nor the approximate doping levels mentioned here are intended to be limiting.

Referring to FIG. 9B, in a conventional tunnel junction, the conduction band (Ec) and the valence band (Ey) of p-type gallium nitride layer 111 lie above the Fermi energy level (Ef). While the conduction band and the valence band of n-type gallium nitride layer 112 lie below the Fermi level. Band bending can be seen to occur in this figure as the p-type bands bend down to join the n-type bands, and the n-type bands bend up to join the p-type bands. (For simplicity, and since all acceptors are ionized in the band-bending region in any case, the complication of incomplete ionization of acceptors in p-type GaN is ignored in FIG. 9B). In typical junctions, depletion region 119, also called the high field region, can be seen to extend partially into layer 111 and partially into layer 112. In tunnel junctions, this distance 19 is also referred to as the tunnel junction distance, or tunnel junction width. This is an indication of the distance a charge carrier will have to tunnel from position 114 in the conduction band of n-type material 112, across tunnel junction width 119, into position 115 in the valence band of the p-type material 111. It is this distance 119 that is to be reduced by manipulating the polarization of the semiconductor materials that make up the structure.

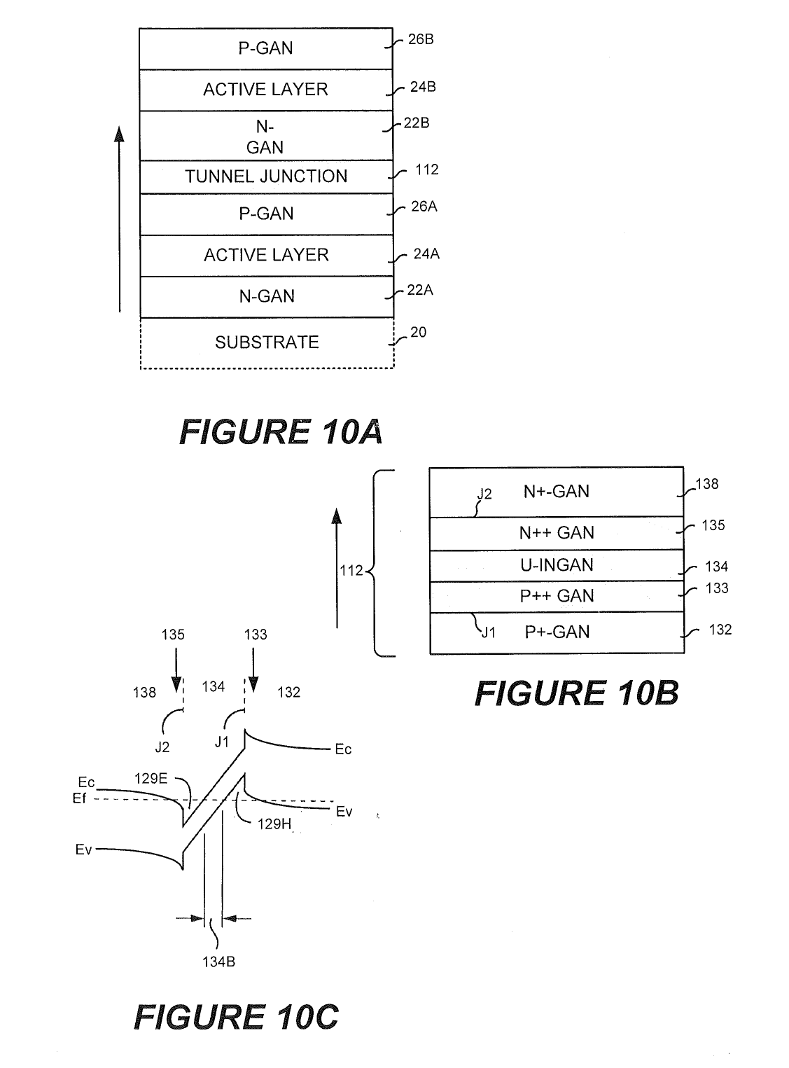

FIG. 10A illustrates an optoelectronic device 100 which contains a low resistance tunnel junction according to some embodiments. The device 100 includes an optional substrate 120, which may be a growth substrate and/or a carrier substrate. The substrate 120 may include, for example, silicon carbide, GaN, sapphire, ZnO, MN, silicon, et. In one embodiment, the substrate 120 may be silicon carbide.

The structure 100 includes a first diode structure D1 including an n-type GaN layer 122A, an active layer 124A and a p-type GaN layer 126A, and a second diode structure D2 including an n-type GaN layer 122B, an active layer 124B and a p-type GaN layer 126B on the substrate 120. The direction of growth is indicated by the arrow. A low resistance tunnel junction 112 is provided between the p-type GaN layer 26A and the n-type GaN layer 122B. The low resistance tunnel junction 112 includes a doped heterojunction structure. That is, the tunnel junction 112 includes at least one junction between dissimilar semiconductor materials that reduces the tunneling distance of the junction and permits current to flow from the n-type GaN layer 122B to the p-type GaN layer 126A. In addition, the tunnel junction 112 is doped as discussed in more detail below to further reduce the tunnel resistance and/or tunnel distance of the tunnel junction.

FIG. 10B illustrates one possible structure of a tunnel junction 112 according to some embodiments, and FIG. 10C is a band diagram of the tunnel junction 112 of FIG. 10B. The direction of growth is indicated by the arrow in FIG. 10B. Referring to FIG. 10B, the tunnel junction 112 includes a heavily doped (but less than degenerately doped) p-type GaN layer 132 and a heavily doped (but less than degenerately doped) n-type GaN layer 138. For example, the p-type GaN layer 132 and the n-type GaN layer 138 may have doping concentrations that result in carrier concentrations of less than about 5E18 cm-3.

Heavy doping of these layers induces some degree of band bending in the tunnel junction. To further encourage band bending, a delta-doped layer of p-type GaN 133 is provided at the top of the p-type GaN layer 132, and a delta-doped layer of n-type GaN 135 is provided beneath the n-type GaN layer 134. The delta-doped layers 133, 135 may be extremely heavily doped, and in some cases may be degenerately doped. Delta doping refers to formation of extremely thin, extremely heavily doped layers. Delta doping may permit higher doping levels to be achieved than can be achieved when doping thicker semiconductor layers. In some embodiments, the delta doped layers 133, 135 may have a thickness of about 0.3 nm to about 10 nm, and in some cases may have a thickness of about 1 nm to 3 nm, and a doping concentration of 1E12 to 1E15 cm⁻².

Furthermore, a layer 134 of a different semiconductor material, such as InGaN, is inserted between the p-type GaN layer 132 and the n-type GaN layer 138. Although having a similar crystal structure, InGaN has a narrower bandgap than GaN and forms heterojunctions J1 and J2 at the interfaces with the p-type GaN layer 132 and the n-type GaN layer 138, respectively.

The InGaN layer 134 may be undoped (i.e., unintentionally doped). It will be appreciated that “undoped” and “unintentionally doped” refer to layers that are grown without the intentional introduction of dopant atoms. Undoped nitride layers may still have a conductivity type, typically n-type, and may also have some background dopant levels due to diffusion, reactor memory, and other effects. However, the level of dopants in undoped or unintentionally doped nitride layers is still substantially lower than in doped layers (e.g. at least about two orders of magnitude less).

In one embodiment, the indium gallium nitride layer 134 may be approximately 30 to 100% indium, and between approximately 0.3 to 5 nanometers thick.

Heterojunctions between dissimilar III-nitride materials grown on crystal polar surfaces induce piezoelectric charges at the material interface. This piezoelectric charge can either enhance or diminish band bending depending on the orientation of the charge. Crystal layers grown along the (0001) orientation in the case of Wurtzite gallium nitride, or along the (111) orientation in the case of the zinc-blende gallium arsenide, are two examples of crystal polar surfaces. The Bravais lattice of the Wurtzite structure is hexagonal, with the axis perpendicular to the hexagons usually labeled as the “c” axis or the (0001) orientation. Along this axis the structure can be thought of as a sequence of atomic layers of the same element (e.g. a layer of all gallium atoms followed by a layer of all nitrogen atoms on a surface), built up from regular hexagons. Due to this uniformity, each layer or surface is polarized and possesses either a positive or negative charge; this generates a dipole across the atomic layers. The charge state of each layer depends on its constituent atoms.

Polarization of the materials is related to the ionic strength of the bond within each of the materials. In a gallium nitride bond, the electrons have a slight preference for the nitrogen atom. This slight preference gives the gallium nitride bond a polarity. The gallium atom has a slight positive charge, and the nitrogen atom has a slight negative charge. Growing in a non-polar direction causes these charges to cancel each other out. A given surface will have approximately equal numbers of gallium and nitrogen atoms. Growing gallium nitride in the (0001) direction, however deposits layers of single element composition. Thus a layer with all nitrogen atoms and no gallium atoms will have a negative polarity, while a layer of all gallium atoms and no nitrogen atoms will have a positive polarity.

Gallium nitride has a certain ionic component to its crystal bond, and indium nitride has a different ionic component to its crystal bond, which is further affected by the strain caused by placing the two materials adjacent to each other. Because of this difference, a space charge will develop at the interface of a heterojunction between these different materials. The space charge will essentially perform the same function as doping in a junction, bending the junction bands to reduce the tunnel width. Additionally, the magnitude of the space charge generated by this indium gallium nitride substitution is larger than what may be achieved by degenerate doping of a homojunction made from gallium nitride. This space charge tends to shrink the width of the tunnel junction. The polarization dipole allows the conduction band on the n-type side of the junction to line up to the valence band on the p-type side of the junction. This indium gallium nitride polarization dipole may achieve this effect over a very short distance.

Additionally, InN has a smaller band gap than GaN, and accordingly any InGaN compound semiconductor will have a smaller band gap than GaN. The greater the concentration of indium in the semiconductor, the smaller the band gap will be. A charge carrier tunneling across tunnel junction width will be influenced by this difference in band gap. The reduction in the band gap height, and the polarization formed by the dissimilar material combine to reduce the resistance to tunneling across the tunnel junction by reducing the tunnel junction width and lowering the tunneling energy barrier.

In some embodiments, the distance a charge carrier must tunnel, shown in FIG. 10C, is from position 129E in the conduction band of n-type gallium nitride layer 138 to position 129H in the valence band in p-type gallium nitride layer 132 (or vice-versa). The band bending formed by the space charge has shortened this distance across tunnel junction width over what the distance would have been in the absence of layer 134. The space charge was a function of the polarization of the dissimilar materials from which the structure was grown.

In addition, the tunnel distance is shortened even further by the presence of delta-doped layers 133, 135. In some embodiments, the undoped layer 134 has a thickness chosen to correspond to the tunneling distance from position 129E to position 129H in the presence of the polarization induced dipole and the band bending caused by the doping of layers 132, 133, 135 and 138.

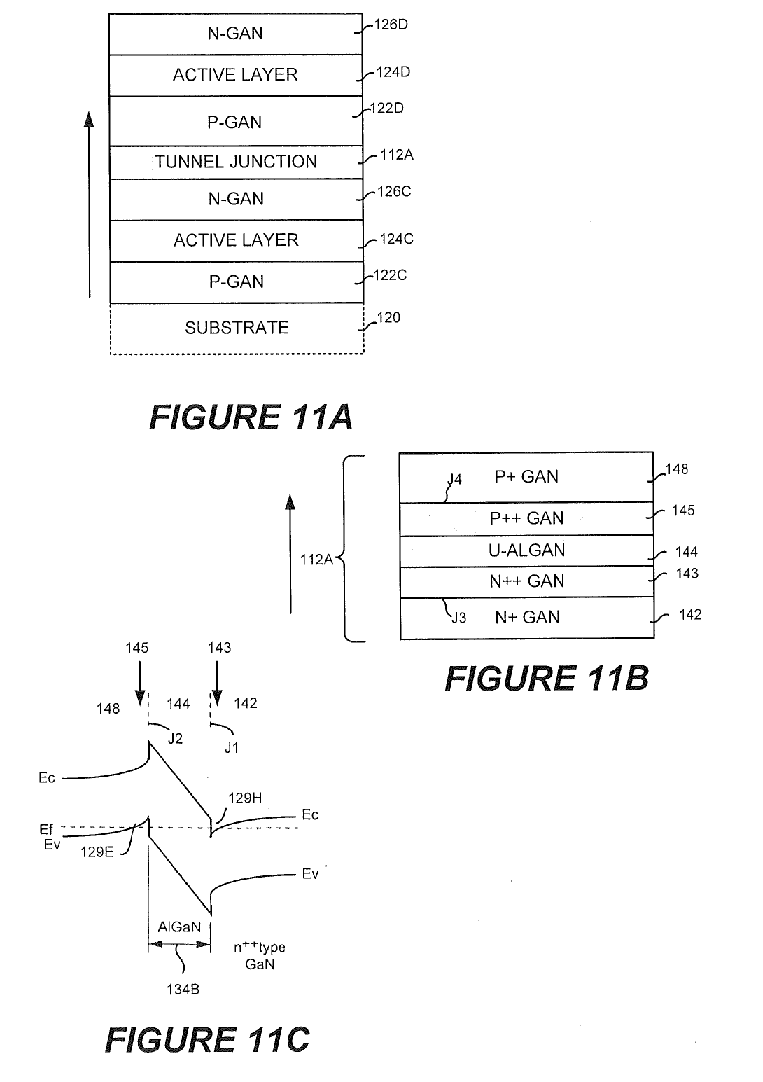

FIG. 11A illustrates a structure including a tunnel junction 112A that includes a material having a wider bandgap than GaN. In the structure of FIG. 11A, the first grown layer 122C is p-type GaN. The structure of FIG. 11A includes a first diode structure D1 including a p-type GaN layer 122C, an active layer 124C and an n-type GaN layer 126C, and a second diode structure D2 including a p-type GaN layer 122D, an active layer 124D and an n-type GaN layer 126D on the substrate 120. The direction of growth is indicated by the arrow. A low resistance tunnel junction 112A is provided between the n-type GaN layer 126C and the p-type GaN layer 122D. The low resistance tunnel junction 112A includes a doped heterojunction structure. That is, the tunnel junction 112A includes at least one junction between dissimilar semiconductor materials that reduces the tunneling distance of the junction and permits current to flow from the p-type GaN layer 122D to the n-type GaN layer 126C. In addition, the tunnel junction 112A is doped as discussed in more detail below to further reduce the tunnel resistance of the tunnel junction.

FIG. 11B illustrates one possible structure of a tunnel junction 112A according to some embodiments, and FIG. 11C is a band diagram of the tunnel junction 112A of FIG. 11B. Referring to FIG. 11B, the tunnel junction 112A includes a heavily doped n-type GaN layer 142 and a heavily doped p-type GaN layer 148. The direction of growth is indicated by the arrow. Degenerate doping of these layers induces a degree of band bending in the tunnel junction. To further encourage band bending, a delta-doped layer of n-type GaN 143 is provided at the top of the n-type GaN layer 142, and a delta-doped layer of p-type GaN 145 is provided beneath the p-type GaN layer 144. The delta-doped layers 143, 145 may be extremely heavily doped, and in some cases may be degenerately doped.

In addition, a layer of a different semiconductor material having a wider bandgap, such as AlGaN, is inserted between the n-type GaN layer 142 and the p-type GaN layer 148. Although having a similar crystal structure, AlGaN has a wider bandgap than GaN and forms heterojunctions J3 and J4 at the interfaces with the n-type GaN layer 142 and the p-type GaN layer 148, respectively.

In some embodiments, the delta doped layers 143, 145 may have a thickness of about 0.3 nm to about 10 nm, and in some cases may have a thickness of about 1 nm to 3 nm, and a doping concentration of 1E12 to 1E15 cm-2.

The AlGaN layer 144 may be undoped (i.e., unintentionally doped). In some embodiments, the aluminum gallium nitride layer 144 may be approximately 30 to 100% indium, and between approximately 0.3 to 5 nanometers thick.

In this embodiment, the degenerately doped n-type gallium nitride layer 142 is grown first, and therefore is adjacent to a substrate (not shown) used to support the structure as it is grown. The direction of growth is indicated by the arrow. The junction polarity of the semiconductor layers in this figure is the opposite of that for the structure in FIG. 10B. Because of the junction polarity change involved in growing n-type gallium nitride layer 142 first, a different dissimilar material is required to be used in layer 144. Aluminum gallium nitride has an ionic component to its crystal bond that is different to gallium nitride, but opposite from indium nitride, and is therefore suitable for this purpose. Heterojunctions J3 and J4 may be abrupt or graded based on empirical requirements of either the growth system or the electrical properties of the structure.

The thickness of layer 144 in FIG. 11B influences the width of the tunnel junction. The approximate locations of the physical structural elements of the tunnel junction with respect to the band gap diagram describing the electrical properties of the structure are displayed across the top of FIG. 11C. The tunnel junction width is the distance the charge carrier has to tunnel from the conduction band of n-type gallium nitride layer 142 at position 129H across the tunnel junction to position 129E in the valence band of the p-type gallium nitride layer 148. The space charge dipole associated with the aluminum gallium nitride layer 144 means the tunneling distance is less than it would have been in the absence of layer 144. The space charge was a function of the polarization of the dissimilar materials from which the structure was grown.

Aluminum nitride has a larger band gap than gallium nitride. Aluminum nitride is generally credited with having a band gap of approximately 6.2 eV, where gallium nitride has a band gap of approximately 3.4 eV. The polarization dipole formed by the presence of the aluminum gallium nitride added to the junction of the gallium nitride tunnel junction will compete with the extra height of the band gap over that transitional area. The physical thickness of layer 144 will therefore, of necessity, be smaller than the physical thickness of layer 134, and the reduction in tunneling resistance will be less. However, it is experimentally possible to determine an optimum thickness for layer 144 that allows the polarity to reduce the width of tunnel junction before the additional height of the band gap diminishes the polarization effect.

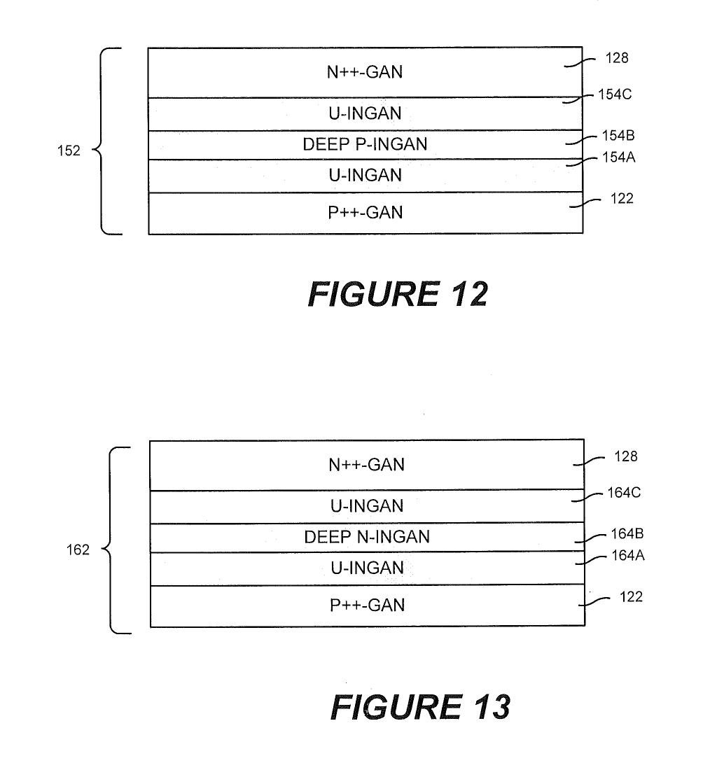

Tunnel junctions according to various other embodiments are illustrated in FIGS. 12-15. Each of the structures shown in FIGS. 12-15 includes a degenerately doped p-type GaN layer 122, a degenerately doped n-type layer 128, and a heterolayer between the p-type layer 122 and the n-type layer 128, grown in the order shown. Because the p-type GaN layer 122 is grown first, the heterolayer 154 comprises a narrower bandgap layer, such as InGaN. However, it will be appreciated that the embodiments of FIGS. 12-15 could be fabricated with the n-type layer grown first, in which case the heterolayer would comprise a wider bandgap layer, such as AlGaN.

Referring to FIG. 12, a heterolayer 154 comprising InGaN is provided between the p-type layer 122 and the n-type layer 128. The heterolayer 154 includes a first undoped sub-layer 154A adjacent the p-type layer 122, a doped sub-layer 154B, and an undoped sub-layer 154C adjacent the n-type layer 128. The doped sub-layer 154B is doped with deep level p-type dopants, such as Zn, Ca etc.

Referring to FIG. 13, a heterolayer 164 comprising InGaN is provided between the p-type layer 122 and the n-type layer 128. The heterolayer 164 includes a first undoped sub-layer 164A adjacent the p-type layer 122, a doped sub-layer 164B, and an undoped sub-layer 164C adjacent the n-type layer 128. The doped sub-layer 164B is doped with deep level n-type dopants, such as C, etc.

Deep level dopants in the doped sub-layers 154B and 164B may facilitate movement of carriers through the tunnel junction by providing intermediate states for the carriers to fill. It is therefore desirable for the doped sub-layers 154B and 164B to be doped with a high enough concentration of deep levels that the deep levels are not filled under equilibrium conditions.

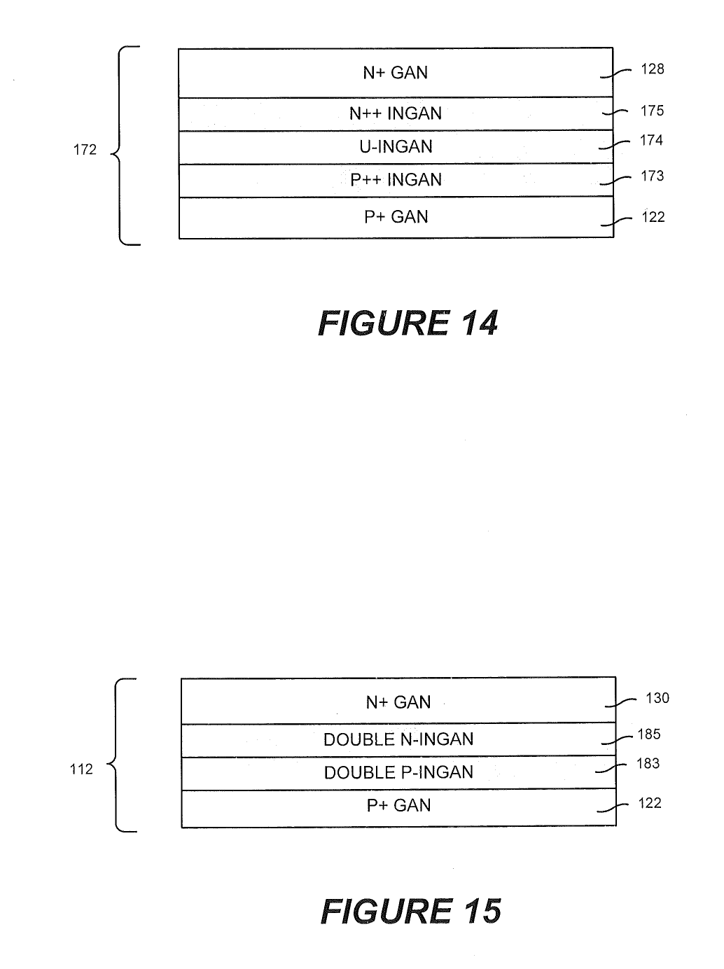

FIG. 14 illustrates a tunnel junction structure in which the delta doped layers 173,175 include InGaN. An InGaN layer having a thickness of about 7 Å and an indium percentage of 50% will cause about 1 eV band bending with a dipole charge of about 4E13 cm⁻². With an InGaN layer that thin, 1E14 cm⁻² delta doping may be used on each side of the tunnel junction. For example magnesium doping could be used in the p-type InGaN layer 173, while silicon, germanium or oxygen could be used in the n-type InGan layer 175.

Having both a large indium content and high delta doping together may enable a thinner tunneling junction thereby enabling lowest resistance. O-doped GaN may be used for heavier doping. Some germanium doping may also be used to avoid cracking that otherwise may occur with heavy doping.

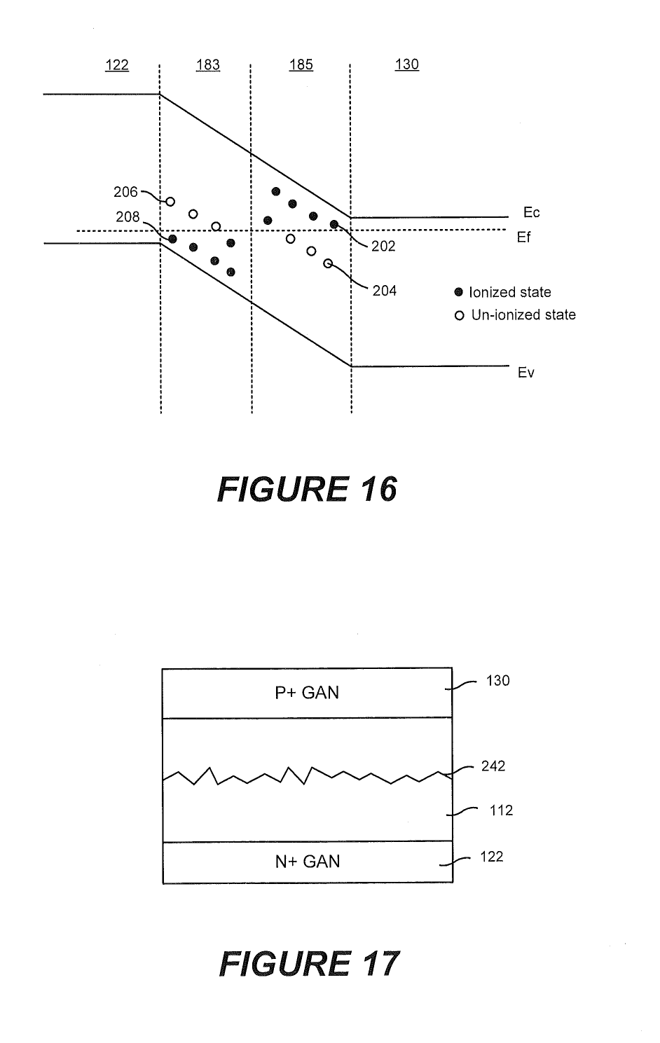

FIG. 15 illustrates a tunnel junction structure including a heterolayer including two sub-layers 183 and 185 that are doped with double p-type and n-type dopants, respectively. FIG. 16 illustrates a band diagram of a tunnel junction doped with doubly-doped layers as shown in FIG. 15. The double doped layers 183 and 185 each include at least one dopant that forms states at multiple different levels within the bandgap of the semiconductor material, such as a deep level state and a shallow level state. Double acceptors in GaN include, for example, Cu, K, Ag, Rb, Na and C. Double donors in GaN include, for example, Ti, Zr, V and Nb. As illustrated in FIG. 19, the double n-type dopant forms shallow level states 202 and deep level states 204, while the double p-type dopant forms shallow level states 208 and deep level states 206.

Double doping within the tunnel junction may provide additional states for carriers to use when tunneling through the junction. In this case, it is important, as shown in FIG. 16, for the deep level states to remain unionized. Thus, for example, at least some of the deep level states generated by double dopants should be deeper than the Fermi level. Stated differently, the double doped layers 183 and 185 should be thin enough that a majority of the deep level states in these layers remain un-ionized.

In some embodiments, as illustrated in FIG. 17, the heterolayer 112 may be formed to have a pitted or rough inner surface, as disclosed in U.S. Pat. No. 7,446,345, issued Nov. 4, 2008, entitled “Light Emitting Devices with Active Layers that Extend into Opened Pits,” which may further concentrate electric fields within the tunnel junction and thereby further decrease the tunneling width of the junction.

In situ growth of a material such as SiNx to partially mask and concentrate electrical fields may be helpful (Si and is also an n-type dopant in GaN so adjacent region maybe n++). A thin SiN layer may be formed to avoid forming a continuous layer. Other materials such as SiO₂, Al₂O₃, gallium nitride etc. could also be provided within the tunnel junction to make sharp facets to similar effect, e.g. pits in InGaN or AlGaN layers or use a low temperature layer to produce sharp faceted surfaces and maximize surface area and/or concentrate fields at peaks. Temperature, III/V ratio and composition may all be used to control the morphology of the layer. Also, etch back at in situ or ex situ in temperature and/or chemistry could be used to change the morphology of the layer, for example high-temperature, H₂, HCl, CL₂, etc.

Before later layers are formed for more LEDs, the growth layer may be smoothed over again by choosing proper temperature, III/V ratio and alloy (for example high-temperature, high ammonia gallium and nitrogen).

For light emitting devices, the tunnel junction should be transparent (i.e. the tunnel junction should not absorb light generated in the active layer), so thick indium gallium nitride layers should be used. Thin InN or InGaN monolayers can be made so that there is no thinner or lower indium nitride in the device. To increase transparency and increase band bending over the shortest thickness, it may be desirable to use the same growth conditions as are used for the quantum well in the active layer, but reduce the growth time so that the well is substantially narrower and the quantum confinement shifts the energy of the tunnel junction InGaN to be higher than that of the emitting well so it remains transparent.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A light emitting diode device, comprising:
a first diode structure;
a second diode structure on the first diode structure; and
a conductive junction between the first diode structure and the second diode structure;
wherein the conductive junction comprises a transparent conductive layer between the first diode structure and the second diode structure.

2. The light emitting diode device of claim 1, wherein the transparent conductive layer comprises a transparent conductive oxide.

3. The light emitting diode device of claim 2, wherein the transparent conductive oxide comprises indium tin oxide and/or zinc oxide.

4. The light emitting diode device of claim 1, wherein the first diode structure comprises a p-type semiconductor layer, the second diode structure comprises an n-type semiconductor layer, and the transparent conductive layer is interposed between and contacts the p-type semiconductor layer and the n-type semiconductor layer.

5. The light emitting diode device of claim 4, wherein the transparent conductive layer forms an ohmic contact to the p-type semiconductor layer and the n-type semiconductor layer.

6. The light emitting diode device of claim 4, wherein the transparent conductive layer comprises a layered structure including a first transparent conductive layer and a second transparent conductive layer on the first transparent conductive layer, wherein the second transparent conductive layer comprises a different material than the first transparent conductive layer.

7. The light emitting diode device of claim 6, wherein the first transparent conductive layer comprises a metal layer and the second transparent conductive layer comprises a transparent conductive oxide.

8. The light emitting diode device of claim 7, wherein the first transparent conductive layer comprises a first transparent conductive oxide and the second transparent conductive layer comprises a second transparent conductive oxide.

9. The light emitting diode device of claim 6, wherein the first transparent conductive layer forms an ohmic contact to the p-type semiconductor layer and the second transparent conductive layer forms an ohmic contact to the n-type semiconductor layer.

10. The light emitting diode device of claim 4, wherein the transparent conductive layer comprises a plurality of apertures, wherein the p-type semiconductor layer contacts the n-type semiconductor layer through the apertures.

11. The light emitting diode device of claim 10, wherein the transparent conductive layer comprises a first transparent conductive layer, the device further comprising a third diode structure on the second diode structure and a second transparent conductive layer between the second diode structure and the third diode structure.

12. The light emitting diode device of claim 11, wherein the plurality of apertures comprises a first plurality of apertures, the second transparent conductive layer comprises a second plurality of apertures, and the second diode structure contacts the third diode structure through the second plurality of apertures.

13. The light emitting diode device of claim 12, wherein the first plurality of apertures are horizontally offset from the second plurality of apertures.

14. The light emitting diode device of claim 13, wherein the material of the first diode structure and the second diode structure has a first index of refraction, and wherein a material of the first transparent conductive layer and the second transparent conductive layer has a second index of refraction that is different than the first index of refraction.

15. The light emitting diode device of claim 11, further comprising a fourth diode structure on the third diode structure and a third transparent conductive layer between the third diode structure and the fourth diode structure, wherein a distance between the first transparent conductive layer and the second transparent conductive layer is different than a distance between the second transparent conductive layer and the third transparent conductive layer.

16. The light emitting device of claim 11, wherein the first plurality of apertures and the second plurality of apertures are configured to cause the first transparent conductive layer and the second transparent conductive layer to scatter light passing within the light emitting diode device.

17. The light emitting diode device of claim 11, wherein thicknesses of the first second and third diode structures and the first and second transparent conductive layers are selected to cause an effective index of refraction of the light emitting diode device to be less than index of refraction of the material of the first second and third lightning diode structures.

18. The light emitting diode device of claim 11, wherein thicknesses of the first second and third diode structures and the first and second transparent conductive layers are selected to reduce the reflectivity of the structure at a predetermined wavelength of light.

19. The light emitting diode device of claim 1, further comprising a trench through the second light emitting diode structure.

20. The light emitting diode device of claim 19, wherein the trench extends to the first light emitting diode structure.

21. The light emitting diode device of claim 1, further comprising a void between the first light emitting diode structure and the second light emitting diode structure adjacent the transparent conductive layer.

22. A light emitting diode device, comprising:
a diode structure including an n-type layer, an active layer on the n-type layer, and a p-type layer on the active layer; and
a conductive junction on p-type layer opposite the active layer;
wherein the conductive junction comprises a transparent conductive layer.

23. A low resistance tunnel junction structure, comprising:
first and second semiconductor layers, wherein the first layer is non-degenerately doped with n-type dopants, and wherein the second layer is non-degenerately doped with p-type dopants; and
a third semiconductor layer between the first and second semiconductor layers and forming first and second heterojunctions with the first and second layers respectively, the third semiconductor layer having a narrower bandgap than the first and second layers;
wherein the first, second and third layers have an associated natural polarization dipole that causes a tunneling distance between the first and second semiconductor layers to be smaller than it would be in the absence of the third layer; and
a delta-doped region in the first semiconductor layer adjacent the first heterojunction, wherein the first delta-doped region is doped with n-type dopants at a doping concentration greater than 5E18 cm⁻³.

24. The low resistance tunnel junction structure of claim 23, wherein the delta-doped region comprises a first delta-doped region, the structure further comprising:
a second delta-doped region in the second semiconductor layer adjacent the second heterojunction, wherein the second delta-doped region is doped with p-type dopants at a doping concentration greater than 5E18 cm⁻³.

25. The junction structure of claim 23, wherein the third layer is about 0.5 to 10 nanometers thick.

26. The junction structure of claim 23, wherein the structure comprises a periodic table group III-nitride material system.

27. The junction structure of claim 23, wherein the third layer comprises indium gallium nitride (InxGayN), where x+y=1 and x>0 or aluminum gallium nitride (AlxGayN), where x+y=1 and x>0.

28. The junction structure of claim 23, wherein the third layer forms abrupt transitions with the first and second layers.

29. The junction structure of claim 23, wherein the third layer forms graded transitions with the first and second layers.

30. The junction structure of claim 23, wherein the third layer comprises an impurity that forms both deep level and shallow level bandgap states within the third layer that further reduces the tunneling distance between the first and second semiconductor layers.

31. The junction structure of claim 23, wherein the third layer comprises a first sub-layer doped with a double p-type dopant that forms both deep level and shallow level acceptor states and a second sub-layer doped with a double n-type dopant that forms both deep level and shallow level donor states.

32. The junction structure of claim 23, wherein the first and second sub-layers are about 0.3 to 5 nanometers thick.
